(19) United States
(12) Patent Application Publication
(10) Pub. No.: US 2002/0037610 A1
(43) Pub. Date: Mar. 28, 2002

(54) MOS structure and method for fabricating the structure

(76) Inventor: Horng-Huei Tseng, Hsinchu (TW)

Correspondence Address: J C Patents Inc, 4 Venture, Suite 250, Irvine, CA, 92618, US

(21) Appl. No.: 09/734,283

(22) Filed: Dec. 11, 2000

Related U.S. Application Data
(63) Continuation-in-part of application No. 09/670,210, filed on Sep. 25, 2000.

(51) Int. Cl. H01L 29/76; H01L 21/336; H01L 31/062; H01L 21/8234; H01L 29/94; H01L 31/113; H01L 31/119

(52) U.S. Cl. 438/197; 257/288; 257/368; 257/377; 257/382; 438/300; 257/383

(57) ABSTRACT

The invention is about a method for forming a MOS device. A substrate is provided first. A field oxide layer is formed on the substrate to define an active region. A gate structure is formed on the active region, where the gate structure has a gate oxide layer, a first gate layer, and a cap layer on the gate layer. The field oxide layer has a height substantially equal to the cap layer. The cap layer is thicker than the first gate layer, such as about three times of the first gate layer. A lightly doped region is formed in the substrate. A spacer is formed on a sidewall of the gate structure. A source/drain region is formed at each side of the gate. An epitaxial silicon layer is selectively formed on the source/drain region with a height substantially equal to the height of the first gate layer. The cap layer is removed to form a trench that exposes the first gate layer. A conductive layer is deposited on the first gate layer and the epitaxial silicon layer within the source/drain region. The conductive layer has a thickness of about equal to the cap layer, so that a portion of the conductive layer with the trench forms a second gate layer.

### CROSS-REFERENCE TO RELATED APPLICATION

The present application is a continuation in part of Applicant's application serial number Not Assigned filed Sep. 25, 2000, entitled ‘SEMICONDUCTOR STRUCTURE WITH METAL SILICIDE AND METHOD FOR FABRICATED THE STRUCRURE’, currently pending, which is not admitted to be prior art with respect the present invention by its mention in the background.

### BACKGROUND OF THE INVENTION

1. Field of Invention

The present invention relates to semiconductor fabrication. More particularly, the present invention relates to a metal-oxide semiconductor (MOS) structure, where a gate is surrounded by an conductive material.

2. Description of Related Art

As well known in the prior skills, a silicide layer can effectively reduce resistance of a conductive structure. The silicide in the conventional manner is formed by performing a thermal process, so as to trigger a reaction between a refractory metal material and a silicon layer. The refractory metal materials can be, for example, titanium, cobalt, tungsten. The silicon usually is provided by the silicon elements themselves, such as the silicon substrate or the polysilicon gate themselves. The results from this conventional manner usually consumes thickness of the silicon elements, particularly such as the source/drain junction depth. If the junction depth is insufficient, the MOS transistor would have poor performance. Also and, the silicide cannot have precise and sufficient thickness on the gate layer, so as to effectively improve conductivity. A conventional method to form a self-aligned silicide contacts formed from deposited silicon is disclosed in U.S. Pat. No. 6,093,967. However, only silicide formed on the junction region.

### SUMMARY OF THE INVENTION

The invention provides a method for forming a MOS device. The method includes first providing a substrate. A field oxide layer is formed on the substrate to define an active region. A gate structure is formed on the active region, where the gate structure has a gate oxide layer, a first gate layer, and a cap layer on the gate layer. The field oxide layer has a height substantially equal to the cap layer. The cap layer is also thicker than the first gate layer, such as about three times of the first gate layer. A lightly doped region (LDD) or extension doped region is formed in the substrate. A spacer is formed on a sidewall of the gate structure. A source/drain region is formed in the substrate at each side of the gate. An epitaxial silicon layer is selectively formed on the source/drain region with a height substantially equal to the height of the first gate layer. The cap layer is removed to expose the first gate layer, whereby a trench is formed abutting the spacer. A conductive layer, such as tungsten, is selectively deposited on the silicon surface, where the silicon surface includes, for example, the first gate layer and the epitaxial silicon layer on the source/drain region. The conductive layer has a thickness of about equal to the cap layer, so that a portion of the conductive layer with the trench forms a second gate layer.

In the foregoing, the gate structure includes the first gate layer and the second gate layer. The first gate layer can include polysilicon and the second gate layer can include the conductive layer with higher conductivity. The interconnecting structure contacting on the source/drain region has also a two-layer structure.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A-1C are cross-sectional views, schematically illustrating the process to form the MOS device, according to one preferred embodiment of this invention.

### DESCRIPTION OF THE PREFERRED EMBODIMENTS

The present invention is directed to a formation of a metal-oxide semiconductor (MOS) device. The method allows a cap layer on the gate layer to be removed and replaced with a conductive layer having higher conductivity. A two-layer conductive layer also fills the cavity space between the spacer and the field oxide layer, so that the two-layer structure is also formed on the source/drain region of the MOS transistor with sufficient thickness without consuming the junction depth. Each layer of the two-layer conductive layer has thickness about respectively equal to the two-layer gate structure. An embodiment is provided in the follow for descriptions.

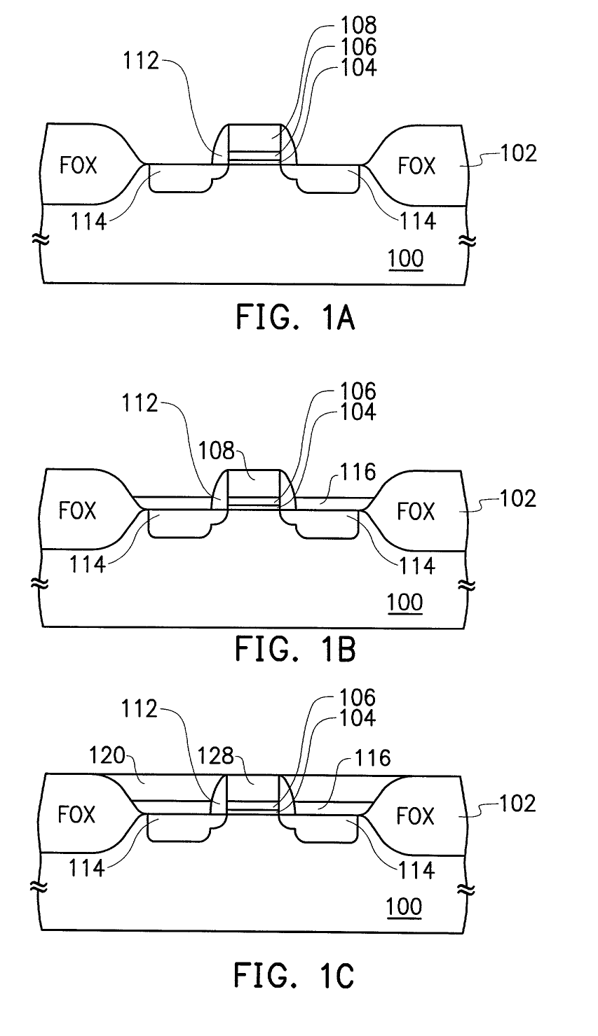

FIGS. 1A-1C are cross-sectional views, schematically illustrating the process to form a MOS semiconductor device, according to one preferred embodiment of this invention.

In FIG. 1A, a gate structure is formed at an active region on a substrate. This structure can be formed by a few of steps. First, a substrate 100 is provided. A field oxide (FOX) layer 102 is formed on the substrate 100 to define the active region. The thickness of the FOX layer is about 2000 angstroms. A typical gate structure is formed on the substrate at the active region. The gate structure includes a gate oxide layer 104 on the substrate 100, a gate layer 106 on the gate oxide layer 104, and a cap layer 108 on the gate layer 106. The gate oxide layer usually is about 50-300 angstroms, the gate layer 106 usually is about 500 angstroms, and the cap layer 108 usually is about 1500 angstroms. In general, the cap layer 108 is thicker than the gate layer 106. The gate layer 106 usually includes, for example, polysilicon and the cap layer 108 usually includes, for example, silicon nitride layer. Usually, a spacer 112 is formed on a sidewall of the gate structure. A source/drain region 114 with a doped extension region under the spacer 112 is also formed in the substrate 100 at each side of the gate structure. The spacer 112 can be formed by depositing a dielectric layer with a thickness of about 300-2000 angstroms, and etching back the dielectric layer to expose the cap layer 108. The material of the spacer 112 is chosen to be different the material of the cap layer 108. Preferably, the spacer 112 includes silicon oxide.

It should be noted that the cap layer 108 has a height substantially equal to the FOX layer 102. This can be done by, for example, depositing the gate oxide layer 104, the gate layer 106, and the cap layer 108 in a blanket deposition manner. Before pattering them to form the gate structure, a CMP process is performed to have the FOX layer 102 and the cap layer 108 with about the same height. The cap layer 108 includes material different from the FOX layer 102. Preferably, the cap layer 108 includes silicon nitride. The spacer 112 includes also silicon oxide different from the material of the cap layer 108.

A cavity space between the spacer 112 and the FOX layer 102 is naturally formed after the MOS transistor is formed. The structure as shown in FIG. 1A can be achieved by various manners. The foregoing manner is only an example. In general, the gate structure can be any conductive structure layer. The source/drain region 114 are not absolutely necessary to be included.

In FIG. 1B, an epitaxial silicon layer 116 is selectively formed on the source/drain region 114 between the FOX 102 and the spacer 112. The thickness of the epitaxial silicon layer 116 preferably is about equal to the gate layer 106. However, a height of the epitaxial silicon layer 116 is about equal to the height of the gate layer 106.

In FIG. 1C, the cap layer 108 of FIG. 1B is removed by for example, wet etching. Since the material of the cap layer is properly chosen, a proper etching selective ratio on the cap layer 108 can be set. After the cap layer 108 is removed, a trench originally occupied by the cap layer 108 is formed.

Then, a conductive layer is selectively formed to fill the trench, resulting in the conductive layer 128 by, for example, chemical mechanical deposition (CVD). The selective deposition can be, for example, achieved due to the epitaxial silicon and the poly-silicon that provide the seed surface. Simultaneously, the conductive layer also fills the cavity between the FOX layer 102 and the spacer 112, resulting in the conductive layer 120. In other words, the conductive layer 128 and the conductive layer 120 are simultaneously formed, both of which has a height about equal to the original height of the cap layer 108 of FIG. 1B. It also means that the thickness of the conductive layers 120, 128 is about equal to the thickness of the cap layer 108. The total height of the gate structure is about 2000 angstroms.

Alternatively, the conductive layer 120, 128 can be formed through a conventional manner by depositing the preliminary conductive layer, and polishing the conductive layer.

As shown in FIG. 1C, the gate structure now includes the gate oxide layer 104, the polysilicon gate layer 106 and the conductive layer 128. If the gate structure is modified into a conductive structure layer, the gate oxide layer 104 may be not necessary.

Moreover, the conductive layers 120, 128 can include tungsten, aluminum, metal or any material with sufficient conductivity. The conductive layers can be formed by, for example, selective deposition. Actually, the conductive layer 120 and 128 can be converted into conductive silicide layer by performing a further thermal process. The conductive silicide layer can include, for example, tungsten silicide, titanium silicide, or cobalt silicide.

It still has several subsequent processes to accomplish the intended device, but those process are known by the skilled artisans. No further descriptions are provided here.

In summary, the invention has several features as follows:

1. The invention uses the cap layer 108 to reserve a trench space, which can filled with a conductive layer having higher conductivity. The conductive layer 128 on the gate layer 104 can have sufficient thickness to effectively reduce the resistance without consume the polysilicon material of the gate. As a result, the gate structure includes two conductive layers.

2. Through the CMP process using the FOX layer as a polishing stop, the cap layer can have a height substantially equal to the FOX layer, so that the FOX can be used as a polishing stop when the silicide layer is polished.

3. The two-layer conductive layer is formed on the source/drain region with the same height as the gate structure.

4. Thickness of each layer of the two-layer conductive layer is respectively equal to thickness of each of the gate structure.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A method for forming a semiconductor device, the method comprising:
providing a substrate, on which there is a field oxide (FOX) layer to define out an active region;
forming a metal-oxide semiconductor (MOS) device on the substrate at the active region, wherein the MOS transistor includes a gate structure with a spacer on its sidewall, and a source/drain region in the substrate at each side of the gate structure, the gate structure has a gate oxide layer on the substrate, a first gate layer on the gate oxide layer, and a cap layer on the first gate layer, wherein the cap layer and the FOX layer have about the same height, and the cap layer is thicker than the first gate layer;
selectively depositing an epitaxial silicon layer on the source/drain region with a thickness about equal to a thickness of the first gate layer;
removing the cap layer to leave a trench that expose the first gate layer; and
forming a conductive layer to fill the trench on the first gate layer so as to form a second gate layer on the first gate layer, wherein a cavity above the epitaxial silicon layer within the source/drain region is also filled by the conductive layer.

2. The method of claim 1, wherein the cap layer comprises a material different from that of the spacer and the FOX layer.

3. The method of claim 1, wherein the cap layer comprises silicon nitride.

4. The method of claim 1, wherein the spacer layer comprises silicon oxide.

5. The method of claim 1, wherein the step of forming the MOS device on the substrate comprises:
sequentially forming a preliminary gate oxide layer, a preliminary gate layer, and a preliminary cap layer over the substrate;
polishing materials over the substrate, whereby the preliminary cap layer and the FOX layer have about the same height;
patterning the preliminary gate oxide layer, the preliminary gate layer, and the preliminary cap layer to form the gate structure; and
forming the spacer on the sidewall of the gate structure and the source/drain region in the substrate at each side of the gate structure.

6. The method of claim 1, wherein the gate oxide layer comprises a thickness of a bout 50-300 angstroms.

7. The method of claim 1, wherein the first gate layer comprises a thickness of about 500 angstroms.

8. The method of claim 1, wherein the cap layer comprises a thickness of about 1500 angstroms.

9. The method of claim 1, wherein the first gate layer comprises polysilicon.

10. The method of claim 1, wherein the second gate layer comprises tungsten.

11. The method of claim 1, further comprising a thermal process to convert the conductive layer into a conductive silicide.

12. The method of claim 11, wherein the conductive silicide layer comprises one selected from the group consisting of tungsten silicide, titanium silicide, and cobalt silicide.

13. A metal-oxide semiconductor (MOS) structure, comprising:
a substrate;
a field oxide (FOX) layer on the substrate to define out an active region;
a conductive structure layer formed on the active region, wherein the conductive structure comprises a first conductive layer and a second conductive layer in which the second conductive layer is thicker than the first conductive layer;
a spacer formed on a sidewall of the conductive structure layer;
an epitaxial silicon layer form on the substrate at each side of the conductive structure layer, abutting the spacer, wherein a thickness of the epitaxial silicon layer is about equal to a thickness of the first conductive layer of the conductive structure layer;
a third conductive layer formed on the epitaxial silicon layer with a same material and a same thickness with those of the second conductive layer of the conductive structure layer.

14. The MOS structure of claim 13, wherein the third conductive layer and the second conductive layer of the conductive structure layer are actually in one single layer with two portions.

15. The MOS structure of claim 13, wherein the second conductive layer is about three times of the first conductive layer.

16. The MOS structure of claim 13, wherein the first conductive layer comprises polysilicon.

17. The MOS structure of claim 13, wherein the second conductive layer comprises one selected from a group consisting of tungsten, aluminum, and pure metal.

18. The MOS structure of claim 13, wherein second conductive layer is formed by selective deposition.

19. The MOS structure of claim 13, wherein the second conductive layer and the third conductive layer comprise one selected from the group consisting of tungsten silicide, titanium silicide, and cobalt silicide.

20. The MOS structure of claim 13, wherein the conductive structure layer comprises a gate structure.
